(19) United States
(12) Patent Application Publication
(10) Pub. No.: US 2006/0273450 A1
(43) Pub. Date: Dec. 7, 2006

(54) Solid-diffusion, die-to-heat spreader bonding methods, articles achieved thereby, and apparatus used therefor

(75) Inventors: Wei Shi, Gilbert, AZ (US); Daoqiang Lu, Chandler, AZ (US); Edward R. Hurley, Chandler, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/143,262

(22) Filed: Jun. 2, 2005

(51) Int. Cl. H01L 23/34

(52) U.S. Cl. 257/706

(57) ABSTRACT

A die and heat spreader are bonded with an intermetallic thermal interface material (TIM). The bonding process is carried out in a tool that can control conditions such that fluxing is not required. An article including an intermetallic TIM between a die and a heat spreader is provided in a computing system. A tool for achieving intermetallic TIM includes a press and a heating element for the process.

### TECHNICAL FIELD

Embodiments relate generally to integrated circuit fabrication. More particularly, embodiments relate to heat management technology with microelectronic devices.

### TECHNICAL BACKGROUND

Heat spreaders are used to remove heat from structures such as an integrated circuit (IC). An IC die is often fabricated into a microelectronic device such as a processor. The increasing power consumption of processors results in tighter thermal budgets for a thermal solution design when the processor is employed in the field. Accordingly, a thermal interface solution is often needed to allow the die to reject heat more efficiently.

Various techniques have been employed to transfer heat away from an IC. These techniques include passive and active configurations. One passive configuration involves a conductive material in thermal contact with the backside of a packaged IC. This conductive material is often a heat pipe, heat sink, a slug, a heat spreader, or an integrated heat spreader (IHS). A heat spreader is attached proximate the back side of an IC with a thermally conductive material, such as a thermal interface material (TIM).

### BRIEF DESCRIPTION OF THE DRAWINGS

In order to depict the manner in which the embodiments are obtained, a more particular description of embodiments will be rendered by reference to specific embodiments that are illustrated in the appended drawings. Understanding that these drawings depict only typical embodiments that are not necessarily drawn to scale and are not therefore to be considered to be limiting of its scope, the embodiments will be described and explained with additional specificity and detail through the use of the accompanying drawings in which:

FIG. 1 is a computer-image depiction of a photomicrograph that exhibits an intermetallic thermal interface material between a die and a heat spreader according to an embodiment;

FIG. 2 is an elevational cross-section of a semiconductor article during processing according to an embodiment;

FIG. 3 is an elevational cross-section of a tool for achieving a solid, diffusion-bonded die and heat spreader with an intermetallic thermal interface material according to an embodiment;

FIG. 4 is an elevational cross-section of a tool for achieving a plurality of parallel-processed solid, diffusion-bonded dies and heat spreaders, which have intermetallic thermal interface materials according to an embodiment;

FIG. 5 is a flow chart that describes a process flow according to an embodiment; and

FIG. 6 is a cut-away elevation that depicts a computing system according to an embodiment.

### DETAILED DESCRIPTION

Embodiments in this disclosure relate to a thermal interface material (TIM) that is bonded between a die and a heat spreader by solid diffusion.

The following description includes terms, such as upper, lower, first, second, etc., that are used for descriptive purposes only and are not to be construed as limiting. The embodiments of an apparatus or article described herein can be manufactured, used, or shipped in a number of positions and orientations. The terms “die” and “chip” generally refer to the physical object of semiconductor material that is the basic workpiece that is transformed by various process operations into the desired integrated circuit device. A die is usually singulated from a wafer, and wafers may be made of semiconductor, non-semiconductor, or combinations of semiconductor and non-semiconductor materials.

Reference will now be made to the drawings wherein like structures will be provided with like suffix reference designations. In order to show the structures of various embodiments most clearly, the drawings included herein are diagrammatic representations of integrated circuit structures. Thus, the actual appearance of the fabricated structures, for example in a photomicrograph, may appear different while still incorporating the essential structures of the illustrated embodiments. Moreover, the drawings show only the structures necessary to understand the illustrated embodiments. Additional structures known in the art have not been included to maintain the clarity of the drawings.

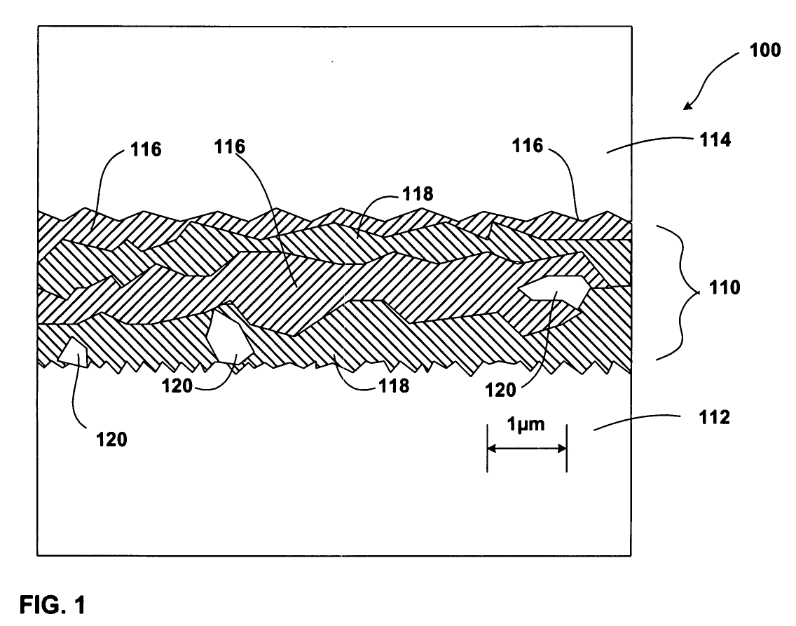

FIG. 1 is a computer-image depiction 100 of a photomicrograph that exhibits an intermetallic thermal interface material 110 between a die 112 and a heat spreader 114 according to an embodiment. In an embodiment, the die 112 is a semiconductor material such as monocrystalline silicon that has been processed into an IC die. In an embodiment, the heat spreader 114 is an integrated heat spreader (IHS) that was presented against the back side of the die and pressed under a vacuum and with slight heating to transform cladding layers into the intermetallic TIM 110. In an embodiment, the intermetallic TIM 110 includes a Cu₆Sn₅ first phase 116 and a Cu₃Sn second phase 118. Similarly where an excess of reactant metals was present, the intermetallic TIM 110 includes a substantially pure third phase 120 of copper.

In an embodiment, the intermetallic TIM 110 includes unreacted materials, such as copper, but the intermetallic materials in the intermetallic TIM 110 are present in at least a plurality quantity. Accordingly for a copper-tin TIM system, the intermetallic TIM 110 may have unreacted copper present, but the intermetallic materials are present in greater quantity.

In an embodiment the intermetallic TIM 110 includes the Cu₆Sn₅ first phase 116 as a presence of about four parts in 10, the Cu₃Sn second phase 118 as a presence of about three parts in 10, and unreacted copper is present as the balance. In an embodiment the intermetallic TIM 110 includes the Cu₆Sn₅ first phase 116 as a presence of about nine parts in 10, the Cu₃Sn second phase 118 as a presence of about one part in 10, and copper is present as a trace amount; less than about 1% as can be assayed by a competent analytical chemist. In an embodiment the intermetallic TIM 110 includes the Cu₆Sn₅ first phase 116 as a presence of greater than the presence of the Cu₃Sn second phase 118. In an embodiment the intermetallic TIM 110 includes the Cu₆Sn₅ first phase 116 in a greater amount than the Cu₃ Sn second phase 118. Other ratios are achievable, even where the unreacted copper is present as the plurality component, and these ratios can be achieved by determining the specific application and altering processing conditions as set forth in this disclosure.

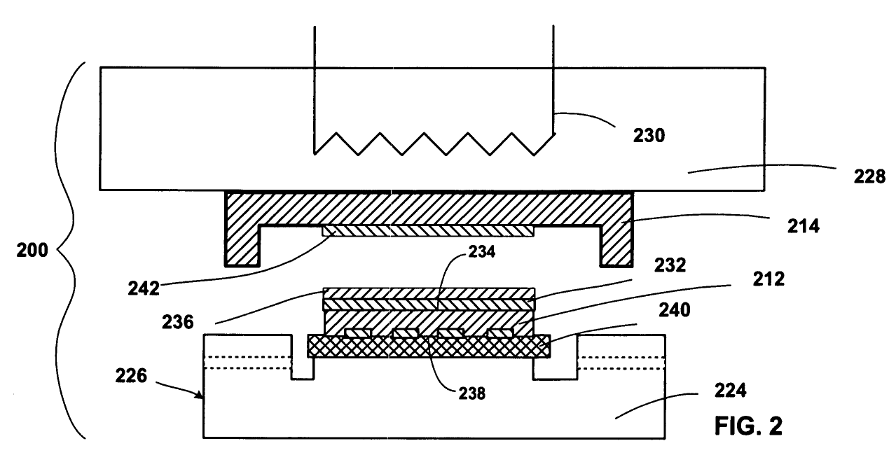

FIG. 2 is an elevational cross-section of a semiconductor article 200 during processing according to an embodiment. A die 212 is disposed upon a die pedestal 224, which is located in a die pocket 226 according to an embodiment. A heat spreader 214 is also present, which is attached to a heat-spreader support platen 228 according to an embodiment. In an embodiment, a heating element 230 is present in the heat-spreader support platen 228. The heating element 230 is depicted as a resistor, but any heating method may be used to achieve embodiments of the semiconductor article, which includes an intermetallic TIM, e.g., the intermetallic TIM 110 depicted in FIG. 1.

The die 212 can be prepared with back-side metallurgy (BSM) layers. In an embodiment, the die 212 is prepared with a copper first layer 232, disposed against the die 212 on the back side 234 thereof. Additionally in an embodiment, the copper first layer 232 has been plated with a tin second layer 236. Typically, the die 212 is pre-plated against the back side 234 with a metal such as titanium. The die 212 rests upon the active surface 238 thereof, upon a flexible pad 240. The heat spreader 214 is also prepared with a tin third layer 242. By “third” layer, it is intended to represent ordinal layers with which both the die 212 and the heat spreader 214 are prepared for the process of forming an intermetallic TIM. Accordingly, the tin third layer 242 can be the only cladding layer upon the heat spreader 214 that is intended to touch the BSM of the die 212.

Materials that are useful in forming an intermetallic TIM, according to an embodiment, are selected in one aspect for lower-temperature processing, which nevertheless results in a high melting-point TIM after the diffusion-bonding process has been completed.

One TIM system includes the tin-copper TIM embodiments as set forth in this disclosure. In an embodiment, the TIM system includes at least a bimetallic compound, which can be presented as constituent elements which have significantly different melting points before diffusion bonding. During diffusion bonding, the low melting point constituent is depleted and converted into an intermetallic TIM with a melting point that is higher than the melting points of either or both of the constituent elements/alloys separately.

In an embodiment, a tin-copper system is presented as at least a first layer 232 and a second layer 236. The process leads to a tin-copper intermetallic. In an embodiment, a gold-indium system is presented as at least a first layer 232 and a second layer 236. The process leads to a gold-indium intermetallic compound. In an embodiment, a gold-indium-tin system is presented as at least a first layer 232 and a second layer 236. The process leads to a gold-indium-tin intermetallic compound. In an embodiment, a tin-silver system is presented as at least a first layer 232 and a second layer 236. The process leads to a tin-silver intermetallic compound. In an embodiment, a gold-tin system is presented as at least a first layer 232 and a second layer 236. The process leads to a gold-tin intermetallic compound. In an embodiment, a silver-indium system is presented as at least a first layer 232 and a second layer 236. The process leads to a silver-indium intermetallic compound. In an embodiment, any combinations of the above two-metal or three-metal systems can be combined according to a specific application.

In an embodiment, the ratios of a first intermetallic phase to a “second” intermetallic phase, and to a “third” metal phase and a “fourth” metal phase as set forth above can be achieved. By way of non-limiting illustration, where a bi-metallic system does not have a likely two-phase intermetallic presence, the intermetallic TIM can be achieved, with or without the presence of unreacted metals as set forth above for the tin-copper TIM system.

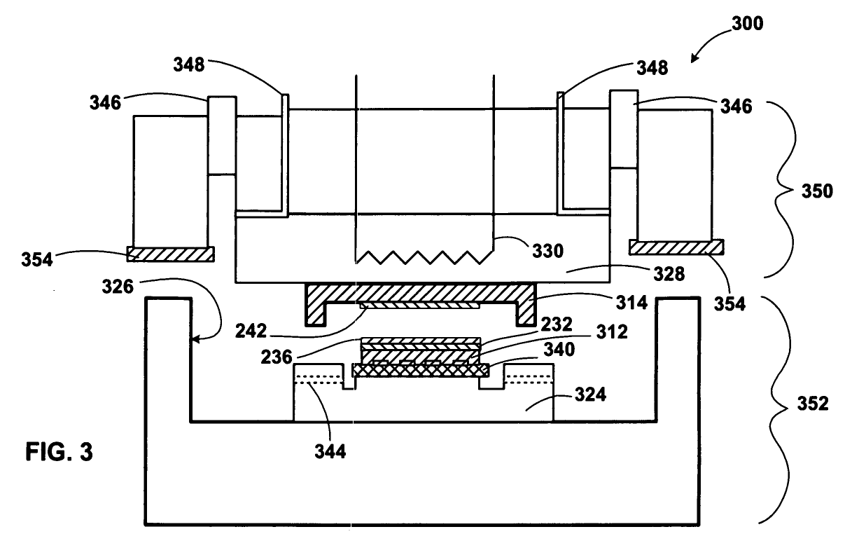

FIG. 3 is an elevational cross-section of a tool 300 for achieving a solid-diffusion-bonded die and heat spreader with an intermetallic thermal interface material according to an embodiment. A die 312 is disposed upon a die pedestal 324, which is located in a die pocket 326 according to an embodiment. The die 312 rests upon a flexible pad 340 such that during the pressing process, the die is protected from cracking and uniformly supported by the pedestal 240.

A heat spreader 314 is also presented, which is attached to a heat-spreader support platen 328 according to an embodiment. In an embodiment, a heating element 330 is present in the heat-spreader support platen 328. The heating element 330 is depicted as a resistor, but any heating method may be used to achieve embodiments of the semiconductor article, which includes an intermetallic TIM, e.g., the intermetallic TIM 110 depicted in FIG. 1.

The tool 300 provides a chamber for the die 312 and the heat spreader 314, in which the solid-diffusion intermetallic TIM can be formed. Adjacent the die pocket 326, the tool 300 includes a gas-pressure reduction via 344 that allows for the exit flow of gas from the die pocket 326, which is proximate the die 312 and the heat spreader 314. In an embodiment, the tool 300 includes a gas-pressure reduction conduit 346 and an inert-gas purge conduit 348. The gas-pressure reduction conduit 346 is supported by a vacuum pump that allows for at least partial evacuation of the tool 300. The inert-gas purge conduit 348 is supported by an inert gas source that allows for flushing out the tool 300 before a process of forming the intermetallic TIM. By combination of the gas-pressure reduction conduit 346 and the inert-gas purge conduit 348, processing can be accomplished without the need to prepare the die 312 and/or the heat spreader 314 with fluxing compounds.

Preparation of the tool 300 includes bringing together an upper section 350 and a lower section 352, and mating them with a vacuum seal 354. Operation of the tool 300 includes elevating the temperature of the heat-spreader support platen 328, to a temperature below the liquidus point of either intermetallic precursor material. Heating, as stated, is carried out by activating the heating element 330 according to an embodiment. After bringing the upper section 350 and the lower section 352 together, ambient gases are removed by flushing the tool 300 with an inert gas therewithin.

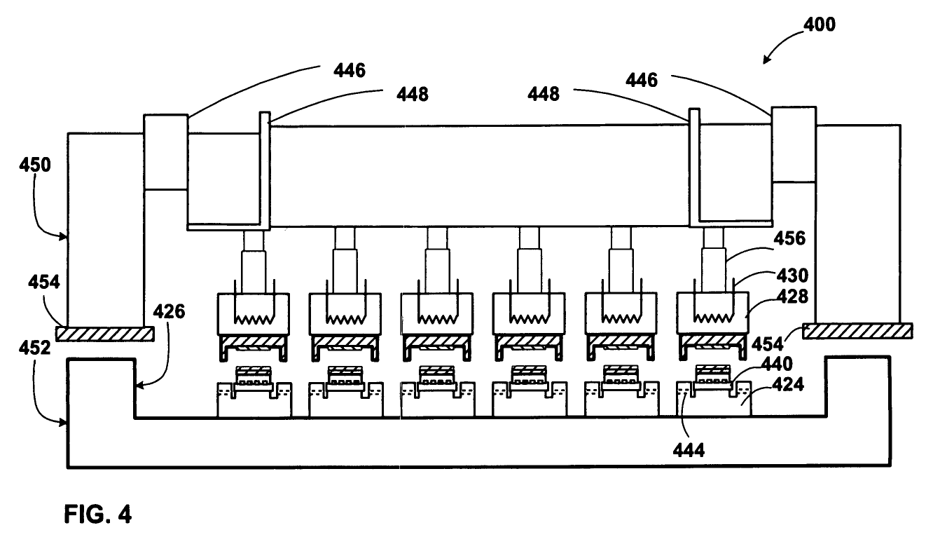

FIG. 4 is an elevational cross-section of a tool 400 for achieving a plurality of parallel-processed solid-diffusion-bonded dice and heat spreaders, which have intermetallic TIMs according to an embodiment. The tool 400 includes a plurality of die pedestals 424, one of which is enumerated, and each of which is located in a die pocket 426 according to an embodiment. A plurality of flexible pads 440 are also provided upon the pedestals 424 such that during the pressing process, the dice are protected from cracking and uniformly supported by the pedestals 424. For each unit within the tool 400, a piston 456 is provided, such that each die being bonded to a heat spreader is afforded individual pressure attention.

A heat-spreader support platen 428 is also present according to an embodiment. In an embodiment, a heating element 430 is present in the heat-spreader support platen 428. The heating element 430 is depicted as a resistor, but any heating method may be used to achieve embodiments of the semiconductor article, which includes an intermetallic TIM, e.g., the intermetallic TIM 110 depicted in FIG. 1.

The tool 400 provides a chamber for a plurality of dice and heat spreaders for which the solid-diffusion intermetallic TIMs can be formed. Adjacent the die pocket 426, the tool 400 includes gas-pressure reduction vias 444 that allows for the exit flow of gas from proximate each individual die. In an embodiment, the tool 400 includes a gas-pressure reduction conduit 446 and an inert-gas purge conduit 448. The gas-pressure reduction conduit 446 is supported by a vacuum pump that allows for at least partial evacuation of the tool 400. The inert-gas purge conduit 448 is supported by an inert gas source that allows for flushing out the tool 400 before a process of forming the intermetallic IMC. By combination of the gas-pressure reduction conduit 446 and the inert-gas purge conduit 448, processing can be accomplished without the need to prepare the dice and/or the heat spreaders with fluxing compounds.

Preparation of the tool 400 includes bringing together an upper section 450 and a lower section 452, and mating them with a vacuum seal 454. Operation of the tool 400 includes elevating the temperature of the heat-spreader support platen 428 to a temperature below the liquidus point of either intermetallic precursor material. Heating, as stated, is carried out by activating the heating element 430 according to an embodiment. After bringing the upper section 450 and the lower section 452 together, ambient gases are removed by flushing the tool 400 with an inert gas therewithin.

In an embodiment, processing conditions include reduced atmosphere, heating, and pressing the intermetallic precursor materials between the die and the heat spreader.

Reference is again made to FIG. 3. In an embodiment, a tin-copper system is used between a semiconductor die structure and a copper-metal heat spreader structure. In a first example, a silicon die 312 is presented within the tool 300 along with an IHS 314 that is heat spreader-grade copper. A substantially pure tin cladding third layer 242 is pre-deposited on the IHS 314. The third layer 242 has substantially the same area and dimensions as the die 312. A tin second layer 236 is also fixed below the IHS 314 with substantially the same area and dimensions as the third layer 242. A copper first layer 232 is pre-deposited on the die 312.

The chamber is sealed, and an inert gas purge is conducted until substantially all the air has been removed from within the tool 300. Next, a vacuum is begun to be established by pumping the nitrogen gas from the chamber. During purge and/or vacuum pumping the heat spreader 314 is preheated by turning on the heating element 330 within the heat-spreader support platen 328. The heat spreader 314, in this embodiment an IHS 314, is heated to about 150° C., and next, the heat spreader 314 is pressed onto the die 312 under pressure sufficient at these conditions to cause solid-diffusion formation of at least one of a Cu₆Sn₅ first phase and a Cu₃Sn second phase. Pressing lasts about 10 seconds, and the pressure does not crack the die 312, which has been thinned in a thickness range from about 25 micrometers to about 200 micrometers.

In a second example, the processing temperature is in a range from about ambient temperature (about 23° C.) and about 180° C. The pressing time is in a range from about 1 second to about 1 minute. In a third example, the processing temperature is in a range from about 100° C. to about 160° C. The pressing time is in a range from about 1 second to about 1 minute. In a fourth example the processing temperature is in a range from about 130° C to about 150° C. The pressing time is in a range from about 1 second to about 1 minute.

In a fifth example, any of the herein-disclosed bimetallic or trimetallic precursor systems are employed, and heating and pressing time are adjusted to achieve an intermetallic phase in the TIM that is present as at least the plurality compound(s).

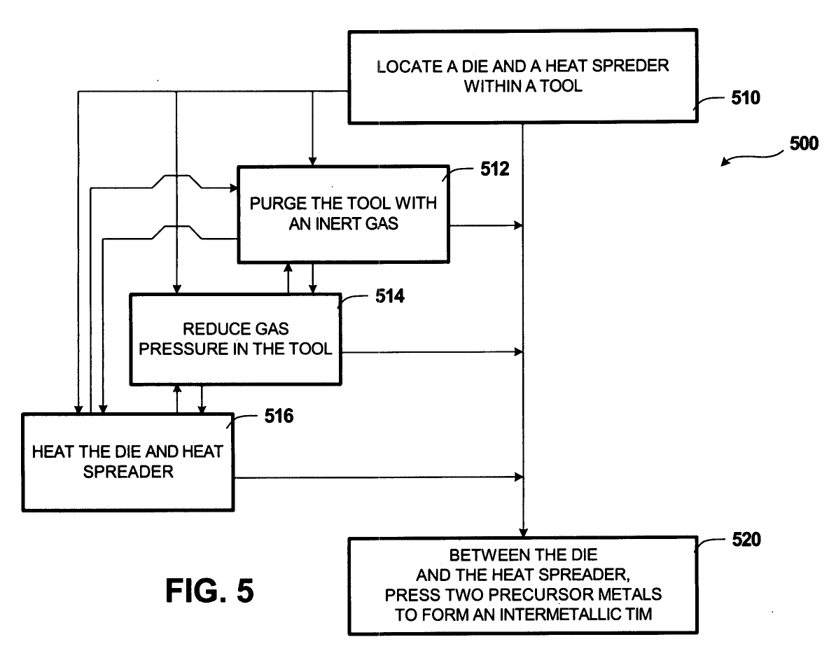

FIG. 5 is a flow chart 500 that describes a process flow according to an embodiment. The various processes are depicted in schematic form and several incidental processes are not illustrated for simplicity.

At 510 the process includes locating a die and a heat spreader within a tool according to an embodiment. The process at 510 can include processing several dice as illustrated in FIG. 4 and described herewithin.

At 520, the process includes pressing at least two metal layers between the die and the heat spreader, under conditions that form an intermetallic TIM. In an embodiment, the process commences and finishes at 520. In an embodiment, the process commences and 510 and finishes at 520.

At 512, the process includes purging the tool to a requisite amount to assure significant contact between the at least two metal precursors, such that a selected amount of an intermetallic TIM is formed. In an embodiment, the process includes purging 512 with a non-oxidizing gas, and pressing 520, after which it terminates at 520.

At 514, the process includes evacuating the tool to a requisite low pressure to assure significant, unoxidized contact between the at least two metal precursors, such that a selected amount of an intermetallic TIM is formed. In an embodiment, the process includes purging 512 and pressing 520, besides evacuating, 514, after which it terminates at 520.

At 516, the process includes heating the heat spreader to a requisite temperature to cause solid-diffusion bonding of the die and heat spreader. Because of processing conditions including purging and evacuating, as well as the purity of the precursor metals, unoxidized contact between the at least two precursor metals is achieved, such that a selected amount of an intermetallic TIM is formed. In an embodiment, the process includes purging 512, vacuum pumping 514, and pressing 520, besides heating 516, after which it terminates at 520.

FIG. 5 illustrates that any combination of purging 512, vacuum pumping 514, and heating 516 can be used along with pressing 520.

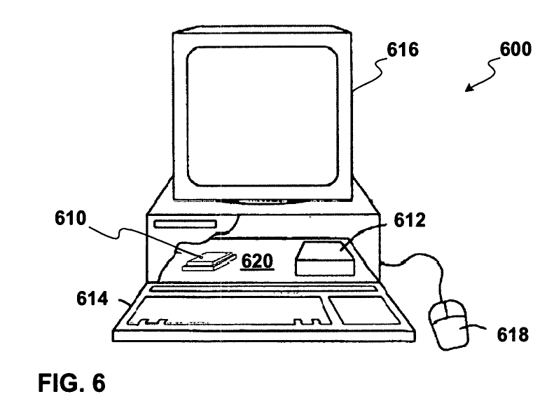

FIG. 6 is a cut-away elevation that depicts a computing system 600 according to an embodiment. One or more of the foregoing embodiments of the intermetallic TIM structures may be utilized in a computing system, such as a computing system 600 of FIG. 6. Hereinafter any embodiment alone or in combination with any other embodiment is referred to as an embodiment(s) configuration.

The computing system 600 includes at least one processor (not pictured), which is enclosed in a package 610, a data storage system 612, at least one input device such as a keyboard 614, and at least one output device such as a monitor 616, for example. The computing system 600 includes a processor that processes data signals, and may include, for example, a microprocessor, available from Intel Corporation. In addition to the keyboard 614, the computing system 600 can include another user input device such as a mouse 618, for example. The computing system 600 can include a structure, after processing as depicted in FIG. 2, including the die 212 and the IHS 214.

For purposes of this disclosure, a computing system 600 embodying components in accordance with the claimed subject matter may include any system that utilizes a microelectronic device system, which may include, for example, at least one of the intermetallic TIM structure embodiments that is coupled to data storage such as dynamic random access memory (DRAM), polymer memory, flash memory, and phase-change memory. In this embodiment, the embodiment(s) is coupled to any combination of these functionalities by being coupled to a processor. In an embodiment, however, an embodiment(s) configuration set forth in this disclosure is coupled to any of these functionalities. For an example embodiment, data storage includes an embedded DRAM cache on a die. Additionally in an embodiment, the embodiment(s) configuration that is coupled to the processor (not pictured) is part of the system with an embodiment(s) configuration that is coupled to the data storage of the DRAM cache. Additionally in an embodiment, an embodiment(s) configuration is coupled to the data storage 612.

In an embodiment, the computing system can also include a die that contains a digital signal processor (DSP), a micro controller, an application specific integrated circuit (ASIC), or a microprocessor. In this embodiment, the embodiment(s) configuration is coupled to any combination of these functionalities by being coupled to a processor. For an example embodiment, a DSP (not pictured) is part of a chipset that may include a stand-alone processor and the DSP as separate parts of the chipset on the board 620. In this embodiment, an embodiment(s) configuration is coupled to the DSP, and a separate embodiment(s) configuration may be present that is coupled to the processor in package 610. Additionally in an embodiment, an embodiment(s) configuration is coupled to a DSP that is mounted on the same board 620 as the package 610. It can now be appreciated that the embodiment(s) configuration can be combined as set forth with respect to the computing system 600, in combination with an embodiment(s) configuration as set forth by the various embodiments of this disclosure and their equivalents.

It can now be appreciated that embodiments set forth in this disclosure can be applied to devices and apparatuses other than a traditional computer. For example, a die can be packaged with an embodiment(s) configuration, and placed in a portable device such as a wireless communicator or a hand-held device such as a personal data assistant and the like. Another example is a die that can be packaged with an embodiment(s) configuration and placed in a vehicle such as an automobile, a locomotive, a watercraft, an aircraft, or a spacecraft.

The Abstract is provided to comply with 37 C.F.R. § 1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. A process comprising:
preparing a back surface of a die; and
diffusion-bonding the die to a heat spreader by achieving a solid-diffusion intermetallic structure as a thermal interface material (TIM).

2. The process of claim 1, wherein the die includes an active surface and a backside surface, wherein the die is prepared with a copper first layer below and on the backside surface, and a tin second layer on the copper first layer, and wherein the heat spreader is prepared with a tin third layer above and on the heat spreader.

3. The process of claim 1, wherein solid-diffusion bonding includes forming the intermetallic structure, selected from a tin-copper intermetallic, Cu₆Sn₅, Cu₃Sn, and combinations thereof.

4. The process of claim 1, wherein diffusion bonding includes processing at least a bimetallic compound that results in the solid-diffusion intermetallic structure, selected from a tin-copper intermetallic, a gold-indium intermetallic, a gold-indium-tin intermetallic, a tin-silver intermetallic, a gold-tin intermetallic, a silver-indium intermetallic, and combinations thereof.

5. The process of claim 1, wherein the solid-diffusion intermetallic structure is achieved at a temperature range between ambient temperature and about 180° C.

6. The process of claim 1, wherein the solid-diffusion intermetallic structure is achieved at a temperature range between about 140° C. and about 160° C.

7. The process of claim 1, wherein the diffusion bonding is carried out under a reduced-pressure atmosphere.

8. The process of claim 1, wherein the diffusion bonding is carried out at a temperature range between ambient temperature and about 180° C., and under a reduced-pressure atmosphere.

9. The process of claim 1, the process further including:
purging with a non-oxidizing gas proximate the die and the heat spreader;
heating at least one of the die and the heat spreader at a temperature range between ambient temperature and about 180° C.; and
pressing intermetallic precursor metals between the die and the heat spreader.

10. The process of claim 1, the process further including:
establishing a less-than-ambient gas pressure proximate the die and the heat spreader;
heating at least one of the die and the heat spreader at a temperature range between ambient temperature and about 180° C.; and
pressing intermetallic precursor metals between the die and the heat spreader.

11. The process of claim 1, the process further including:
purging with a inert gas proximate the die and the heat spreader;
establishing a less-than-ambient gas pressure proximate the die and the heat spreader;
heating at least one of the die and the heat spreader at a temperature range between ambient temperature and about 180° C.; and
pressing intermetallic precursor metals between the die and the heat spreader.

12. A semiconductor article comprising:
a die;
a heat spreader disposed above the die; and
a thermal interface material (TIM) diffused between the die and heat spreader, wherein the TIM includes an intermetallic material.

13. The semiconductor article of claim 12, wherein the intermetallic material is present in at least a plurality quantity of the TIM.

14. The semiconductor article of claim 12, wherein the intermetallic material is present in at least a plurality quantity of the TIM, and wherein the TIM includes one of Cu₆Sn₅ and Cu₃Sn as the at least plurality material.

15. The semiconductor article of claim 12, wherein the intermetallic material is present in at least a plurality quantity of the TIM, wherein the TIM includes Cu₆Sn₅ and Cu₃Sn as the at least plurality material, and wherein Cu₆Sn₅ is present in a greater amount than Cu₃Sn.

16. The semiconductor article of claim 12, wherein the intermetallic material is present in at least a plurality quantity of the TIM, wherein the TIM includes Cu₆Sn₅ and Cu₃Sn as the at least plurality material, and wherein Cu₃Sn is present in a greater amount than Cu₆Sn₅.

17. The semiconductor article of claim 12, wherein the intermetallic structure is selected from a tin-copper intermetallic, a gold-indium intermetallic, a gold-indium-tin intermetallic, a tin-silver intermetallic, a gold-tin intermetallic, a silver-indium intermetallic, and combinations thereof.

18. The semiconductor article of claim 12, wherein the TIM exhibits solid-diffusion intermetallic crystallography.

19. The semiconductor article of claim 12, further including a cladding layer and a die, wherein the cladding layer is disposed on the heat spreader and wherein the cladding layer has an area and dimension equal to or less than the die.

20. A tool comprising:
a die-support pedestal disposed inside a chamber;
a heat-spreader support platen spaced apart and proximate the die-support pedestal, wherein the heat-spreader support platen includes a heating element disposed therein;
a gas-purge conduit that communicates outside the chamber; and
a pressure-reduction conduit that communicates outside the chamber.

21. The tool of claim 20, further including:
a press coupled to one of the heat-spreader support platen and the die-support pedestal, wherein the press has a range of motion to mate the heat-spreader support platen and the die-support pedestal.

22. The tool of claim 20, wherein the die-support pedestal is a first die-support pedestal, further including a plurality of die-support pedestals.

23. The tool of claim 20, wherein the die-support pedestal is disposed in a die pocket.

24. The tool of claim 20, wherein the die-support pedestal is a first die-support pedestal, further including a plurality of die-support pedestals, and wherein each die-support pedestal is disposed in a respective die pocket.

25. The tool of claim 20, further including a cladding layer and a die, wherein the cladding layer is disposed on the heat spreader and wherein the cladding layer has an area and dimension equal to or less than the die.

26. The tool of claim 20, wherein the die-support pedestal is a first die-support pedestal, further including a plurality of die-support pedestals.

27. A system comprising:
a die;
a heat spreader disposed above the die;
a thermal interface material (TIM) diffused between the die and heat spreader, wherein the TIM includes an intermetallic material; and
dynamic random-access memory coupled to the die.

28. The system of claim 27, wherein the intermetallic material is present in at least a plurality quantity of the TIM.

29. The system of claim 27, wherein the intermetallic material is present in at least a plurality quantity of the TIM, and wherein the TIM includes one of Cu₆Sn₅ and Cu₃Sn as the at least plurality material.
